(19) United States
(12) Patent Application Publication
(10) Pub. No.: US 2025/0098259 A1
(43) Pub. Date: Mar. 20, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Ya-Wen CHIU, Hsinchu (TW); Yi-Hua CHENG, Hsinchu (TW); Szu-Ying CHEN, Hsinchu (TW); Zheng-Yang PAN, Hsinchu (TW)

(21) Appl. No.: 18/368,014

(22) Filed: Sep. 14, 2023

(51) Int. Cl. H01L 29/66; H01L 21/762; H01L 27/088

(52) U.S. Cl. CPC H10D 64/021; H01L 21/76224; H10D 30/014; H10D 30/031; H10D 84/83

(57) ABSTRACT

Embodiments of the present disclosure provide semiconductor device structures and methods of forming the same. The method includes forming a first fin structure and a second fin structure from a substrate, depositing a first conformal layer over the first and second fin structures and between the first and second fin structures, depositing a second conformal layer on the first conformal layer, depositing a third conformal layer on the second conformal layer, depositing a fourth conformal layer on the third conformal layer, depositing a first insulating material on the fourth conformal layer between the first and second fin structures, and depositing a second insulating material on the first insulating material. The first and second fin structures are embedded by the second insulating material. The method further includes removing portions of the second insulating material and the first, second, third, and fourth conformal layers to expose the first and second fin structures.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are perspective views of various stages of manufacturing a semiconductor device structure, in accordance with some embodiments.

FIGS. 3-7 are cross-sectional side views of various stages of manufacturing the semiconductor device structure of FIG. 2, in accordance with some embodiments.

FIGS. 8-17 are perspective views of various stages of manufacturing the semiconductor device structure, in accordance with some embodiments.

FIG. 12A is a cross-sectional side view of a portion of the semiconductor device structure of FIG. 12, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide semiconductor device structures and methods of forming the same. In some embodiments, an insulating structure includes multiple conformal layers to prevent epitaxial features from forming on sidewalls of a fin structure.

While the embodiments of this disclosure are discussed with respect to nanostructure channel FETs, implementations of some aspects of the present disclosure may be used in other processes and/or in other devices, such as FinFETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

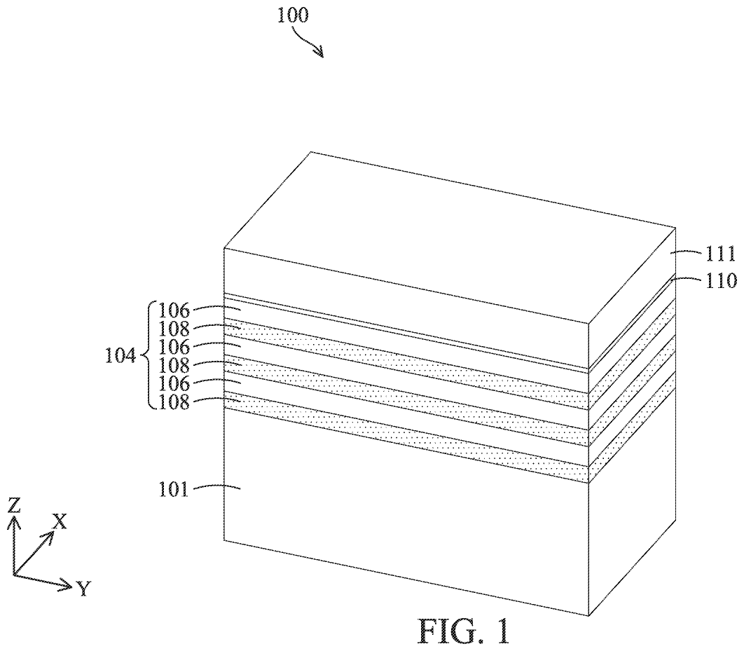

FIGS. 1 to 17 show exemplary processes for manufacturing a semiconductor device structure 100 according to embodiments of the present disclosure. It is understood that additional operations can be provided before, during, and after processes shown by FIGS. 1 to 17, and some of the operations described below can be replaced or eliminated, for additional embodiments of the method. The order of the operations/processes is not limiting and may be interchangeable.

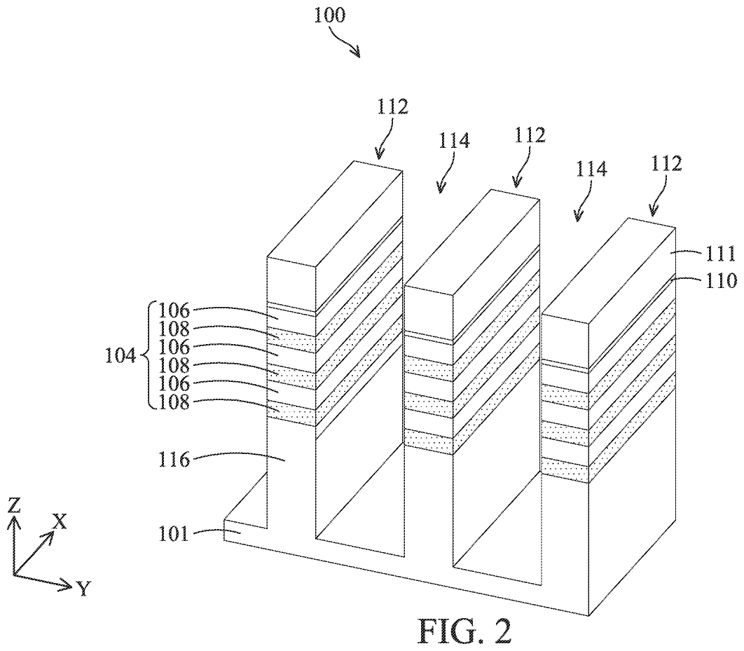

FIGS. 1 and 2 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

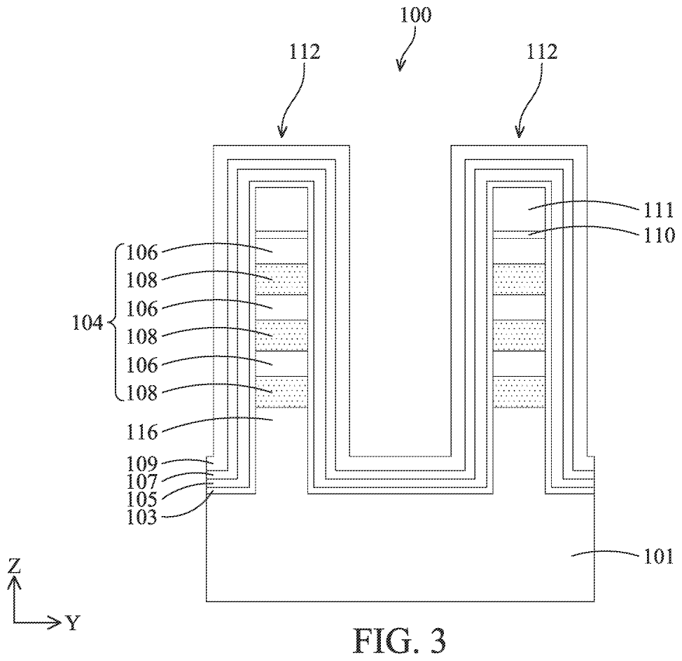

FIGS. 3-7 are cross-sectional side views of various stages of manufacturing the semiconductor device structure 100 of FIG. 2, in accordance with some embodiments. As shown in FIG. 3, after the fin structures 112 are formed, a first conformal layer 103 is deposited on the exposed surfaces of the semiconductor device structure 100, a second conformal layer 105 is deposited on the first conformal layer 103, a third conformal layer 107 is deposited on the second conformal layer 105, and a fourth conformal layer 109 is deposited on the third conformal layer 107. In some embodiments, a semiconductor layer (not shown) may be first formed on the sidewalls of the stack of semiconductor layers 104 and sidewalls of the well portion 116, and the first conformal layer 103 is deposited on the semiconductor layer. In some embodiments, the semiconductor layer is a silicon layer, such as a crystalline silicon layer. The semiconductor layer may have a thickness ranging from about 0.1 nm to about 5 nm. The first conformal layer 103 may include a dielectric material, such as an oxide, for example silicon oxide. In some embodiments, the first conformal layer 103 is formed by an oxidation process. The oxidation process oxidizes the semiconductor materials of the semiconductor device structure 100 to form the first conformal layer 103 including silicon oxide. In some embodiments, the first conformal layer 103 is formed by a conformal process, such as atomic layer deposition (ALD). The first conformal layer 103 may have a thickness ranging from about 0.1 nm to about 10 nm. The first conformal layer 103 may function as an adhesion layer for the second conformal layer 105 or the third conformal layer 107. In other words, the second conformal layer 105 or the third conformal layer 107 may not stick to the semiconductor material of the substrate 101 but does adhere to the first conformal layer 103.

The second conformal layer 105 may include a dielectric material, such as a low-K dielectric material, such as a nitrogen-containing low-K dielectric material. In some embodiments, the dielectric material includes silicon, oxygen, and nitrogen. For example, the dielectric material may be SiON having 31 atomic percent of silicon, 52 atomic percent of oxygen, and 17 atomic percent of nitrogen. The second conformal layer 105 may be formed by any suitable process. In some embodiments, the second conformal layer 105 is formed by a conformal process, such as ALD. The second conformal layer 105 may have a thickness ranging from about 0.1 nm to about 5 nm.

The third conformal layer 107 may include a dielectric material, such as a carbon-containing dielectric material. In some embodiments, the dielectric material includes silicon, carbon, oxygen, and nitrogen. For example, the dielectric material may be SiCON having 26 atomic percent of silicon, three atomic percent of carbon, 62 atomic percent of oxygen, and 9 atomic percent of nitrogen. The third conformal layer 107 may be formed by any suitable process. In some embodiments, the third conformal layer 107 is formed by a conformal process, such as ALD. The third conformal layer 107 may have a thickness ranging from about 0.1 nm to about 5 nm. In some embodiments, the third conformal layer 107 is deposited on the first conformal layer 103, and the second conformal layer 105 is deposited on the third conformal layer 107.

The fourth conformal layer 109 may include a semiconductor material, such as amorphous silicon. The fourth conformal layer 109 may be formed by any suitable process. In some embodiments, the fourth conformal layer 109 is formed by a conformal process, such as ALD. The fourth conformal layer 109 may have a thickness ranging from about 0.1 nm to about 5 nm.

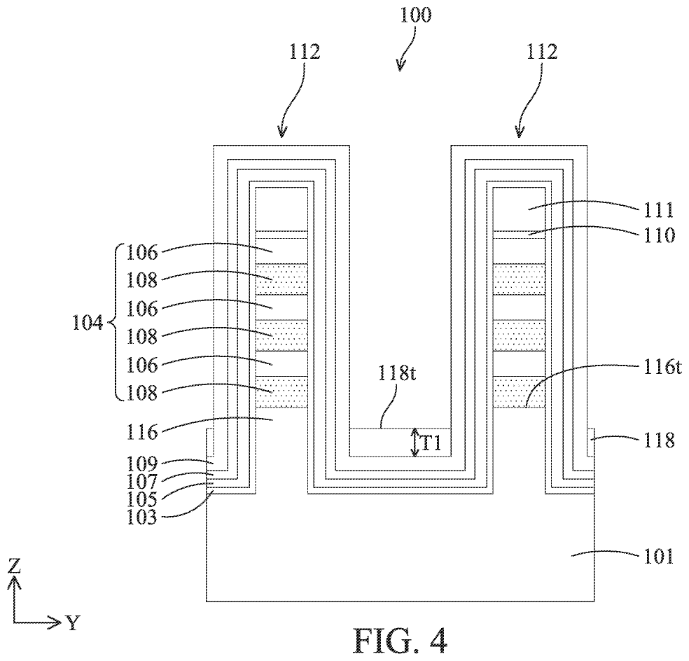

As shown in FIG. 4, a first insulating material 118 is deposited in the trenches 114 between neighboring fin structures 112. The first insulating material 118 is deposited on the fourth conformal layer 109. The first insulating material 118 may be deposited from bottom-up, as shown in FIG. 4. In some embodiments, the first insulating material 118 is deposited by a flowable chemical vapor deposition (FCVD) process. The first insulating material 118 includes a dielectric material, such as silicon oxide, silicon nitride, silicon oxynitride (SiON), SiOCN, SiCN, fluorine-doped silicate glass (FSG), a low-K dielectric material, or any suitable dielectric material. In some embodiments, the first insulating material 118 includes a dielectric material having a K value lower than that of the first, second, and third conformal layers. As shown in FIG. 4, a top surface 118t of the first insulating material 118 may be located at a level substantially below a level of a top surface 116t of the well portion 116. The first insulating material 118 has a thickness T1, as shown in FIG. 4. The thickness T1 may range from about 200 nm to about 300 nm.

After depositing the first insulating material 118, a first anneal process is performed to solidify or harden the first insulating material 118. The first anneal process may be performed at a temperature ranging from about 500 degrees Celsius to about 800 degrees Celsius. In some embodiments, an oxygen-containing gas may be utilized in the first anneal process, and the fourth conformal layer 109 is exposed to and oxidized by the oxygen-containing gas. In addition, oxygen in the first insulating material 118 may diffuse into the portion of the fourth conformal layer 109 in contact with the first insulating material 118 to oxidize the portion of the fourth conformal layer 109. As a result, the fourth conformal layer 109 is converted to an oxide, such as silicon oxide, by the first anneal process. The oxidization of the fourth conformal layer 109 causes the fourth conformal layer 109 to expand, which pushes on the third conformal layer 107, the second conformal layer 105, and the first conformal layer 103. As a result, the densities of the third conformal layer 107, the second conformal layer 105, and the first conformal layer 103 are increased, and the third conformal layer 107, the second conformal layer 105, and the first conformal layer 103 have improved film quality, such as improved wet etch rate (WER), after the first anneal process. In addition, the carbon and nitrogen in the second conformal layer 105 and the third conformal layer 107 may diffuse through the fourth conformal layer 109 into the first insulating material 118 during the first anneal process. The first insulating material 118 with carbon and nitrogen diffused thereinto has improved film quality, such as improved WER.

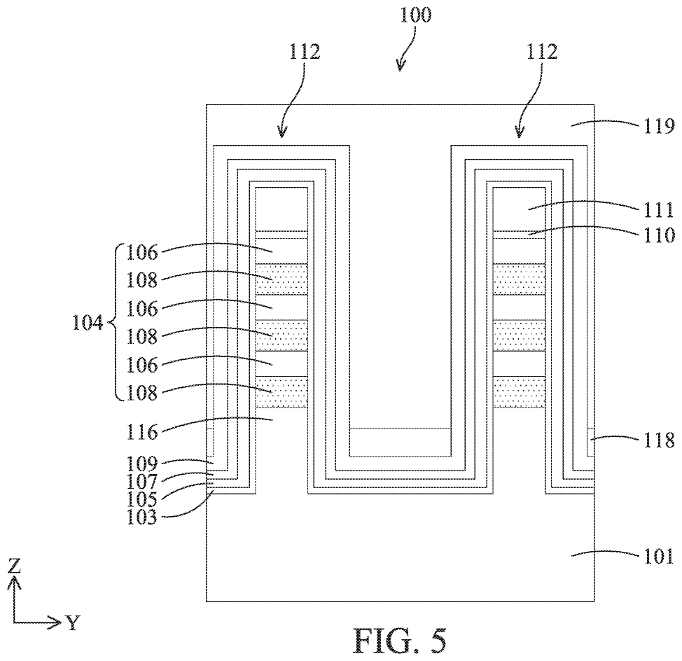

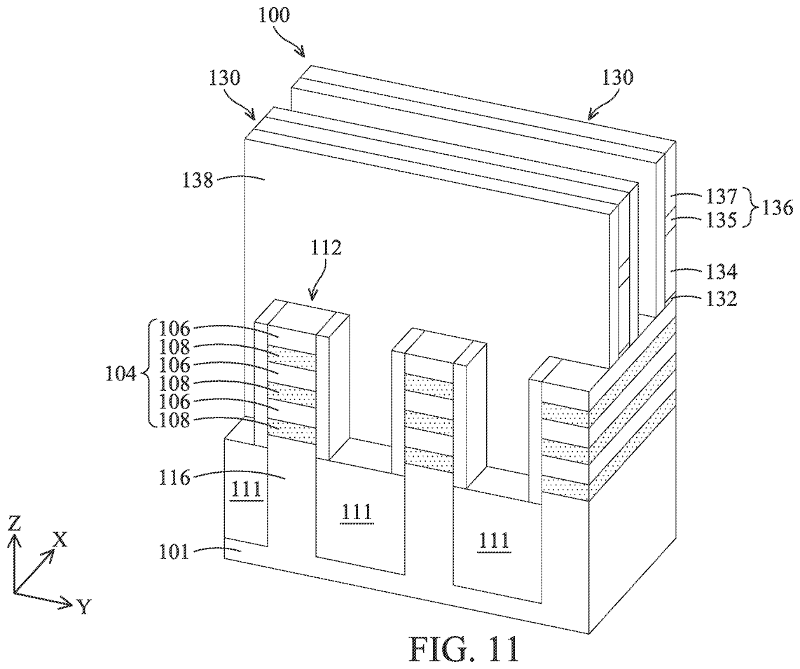

As shown in FIG. 5, a second insulating material 119 is deposited on the first insulating material 118 and over the fin structures 112. The second insulating material 119 is also deposited on the fourth insulating material 109. The second insulating material 119 includes a different material than the first insulating material 118. In some embodiments, the second insulating material 119 is a dielectric material, such as a plasma enhanced oxide (PEOX). The second insulating material 119 may have a slower etch rate during the recess of portions of the fin structures 112 shown in FIG. 11 compared to the first insulating material 118. In other words, the second insulating material 119 protects the first insulating material 118. In some embodiments, the second insulating material 119 including PEOX is formed at a slower rate than the first insulating material 118 formed by FCVD. As shown in FIG. 5, the second insulating material 119 is deposited over the fin structures 112 to embed the fin structures 112.

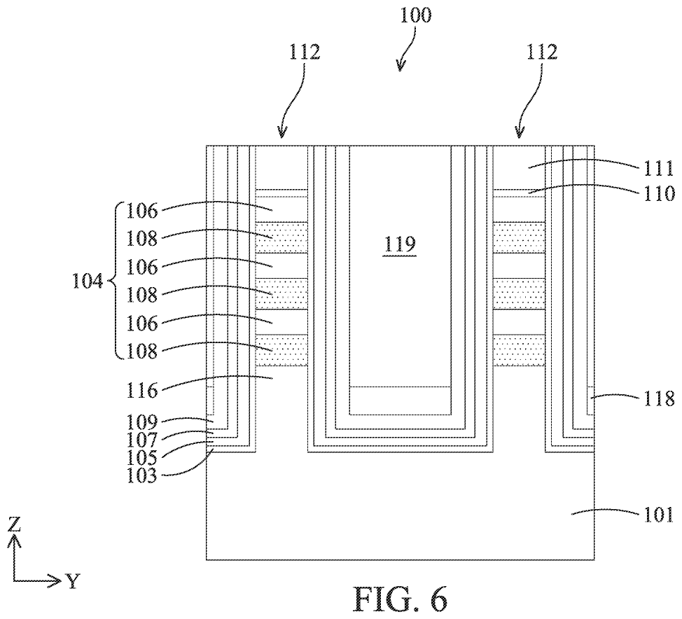

As shown in FIG. 6, the second insulating material 119, the first conformal layer 103, the second conformal layer 105, the third conformal layer 107, and the fourth conformal layer 109 are recessed. In some embodiments, a planarization operation, such as a chemical mechanical polishing (CMP) method, is performed such that the top of the fin structures 112 is exposed. The planarization process removes portions of the second insulating material 119, the first conformal layer 103, the second conformal layer 105, the third conformal layer 107, and the fourth conformal layer 109 formed over the fin structures 112. After the planarization process, a second anneal process is performed to harden the second insulating material 119. The second anneal process may be the same as or different from the first anneal process. The second anneal process may cause further diffusion of carbon and nitrogen from the second and third conformal layers 105, 107 into the first and second insulating materials 118, 119. As a result, the film quality, such as the WER, of the first and second insulating materials 118, 119 may be improved.

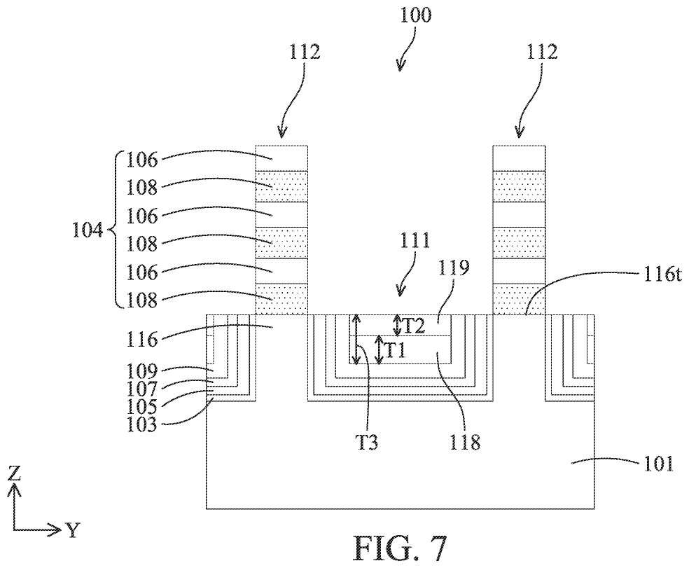

Next, as shown in FIG. 7, one or more etch processes are performed to recess the portions of the second insulating material 119, the first conformal layer 103, the second conformal layer 105, the third conformal layer 107, and the fourth conformal layer 109 formed between adjacent fin structures 112. The resulting insulating structure 111 disposed between adjacent fin structures 112 may be shallow trench isolation (STI). The insulating structure 111 includes the first insulating material 118, the second insulating material 119 disposed on the first insulating material 118, the fourth conformal layer 109 in contact at least three sides of the first and second insulating materials 118, 119, the third conformal layer 107 in contact with the fourth conformal layer 109, the second conformal layer 105 in contact with the third conformal layer 107, and the first conformal layer 103 in contact with the second conformal layer 105.

In some embodiments, because of the different materials of the second insulating material 119, the first conformal layer 103, the second conformal layer 105, the third conformal layer 107, and the fourth conformal layer 109, the resulting top surface of the insulating structure 111 may not be substantially flat. In some embodiments, the top surface of the insulating structure 111 may be curved, such as a concave top surface. The top surfaces of the first, second, third, and fourth conformal layers 103, 105, 107, 109 may be at a location higher than the top surface of the second insulating material 119. In some embodiments, the highest point of the top surface of the insulating structure 111 may be level with or below the top surface 116t of the well portion 116. In some embodiments, the isolation regions 120 are the STI. In some embodiments, the oxide layer 110 and the nitride layer 111 are also removed during the recessing of the second insulating material 119, the first conformal layer 103, the second conformal layer 105, the third conformal layer 107, and the fourth conformal layer 109.

As shown in FIG. 7, after recessing the second insulating material 119, the first conformal layer 103, the second conformal layer 105, the third conformal layer 107, and the fourth conformal layer 109, the second insulating material 119 has a thickness T2. In some embodiments, the thickness T2 ranges from about 50 nm to about 150 nm. The thickness T2 may be substantially less than the thickness T1. A total thickness T3 of the first and second insulating materials 118, 119 may range from about 250 nm to about 450 nm. In some embodiments, the thickness T2 ranges from about 15 percent of the total thickness T3 to about 45 percent of the total thickness T3. As described above, the second insulating material 119 protects the first insulating material 118 and is deposited at a slower rate compared to the first insulating material 118. Thus, if the thickness T2 is less than about 15 percent of the total thickness T3, the second insulating material 119 may not be sufficient to protect the first insulating material 118. On the other hand, if the thickness T3 is greater than about 45 percent of the total thickness T3, the process to form the insulating structure 111 may be too long due to the slower process of depositing the second insulating material 119.

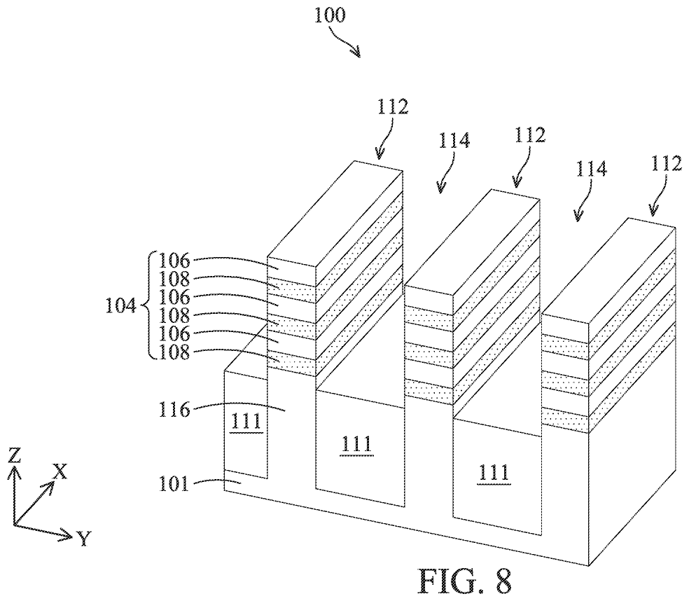

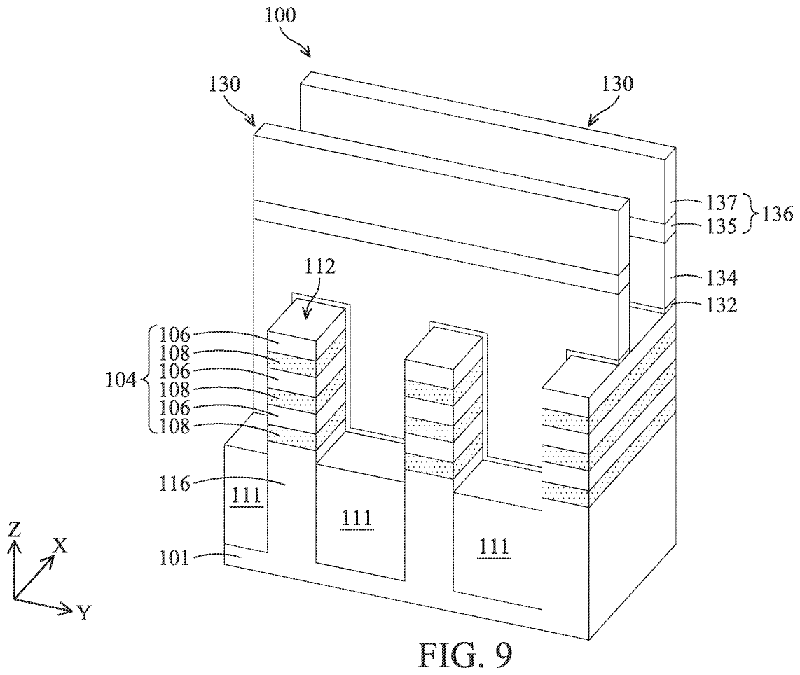

FIGS. 8-17 are perspective views of various stages of manufacturing the semiconductor device structure 100, in accordance with some embodiments. FIG. 8 is a perspective view of the semiconductor device structure 100 shown in FIG. 7. The details of the insulating structures 111 are omitted for clarity. Next, as shown in FIG. 9, one or more sacrificial gate structures 130 are formed over the semiconductor device structure 100. The sacrificial gate structures 130 are formed over first portions of the fin structures 112 and first portions of the insulating structures 111, while second portions of the fin structures 112 and second portions of the insulating structures 111 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

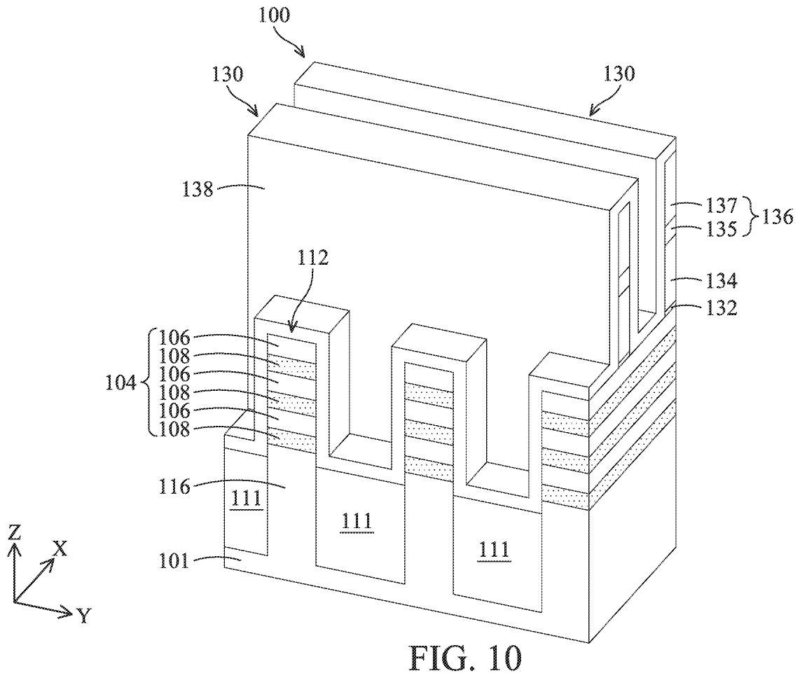

As shown in FIG. 10, a gate spacer layer 138 is formed to cover the sacrificial gate structures 130, the second portions of the fin structures 112, and the second portions of the insulating structures 111. The gate spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the gate spacer layer 138 includes two dielectric layers. In some embodiments, the gate spacer layer 138 is formed by a conformal process, such as an atomic layer deposition (ALD) process. In some embodiments, the gate spacer layer 138 has a thickness ranging from about 2 nm to about 10 nm.

As shown in FIG. 11, an anisotropic etch process is performed to remove horizontal portions of the gate spacer layer 138. The anisotropic etch process may be a selective etch process that does not substantially affect the nitride layer 137, the first semiconductor layer 106, and the insulating structures 111. As a result, the second portions of the fin structures 112 are exposed.

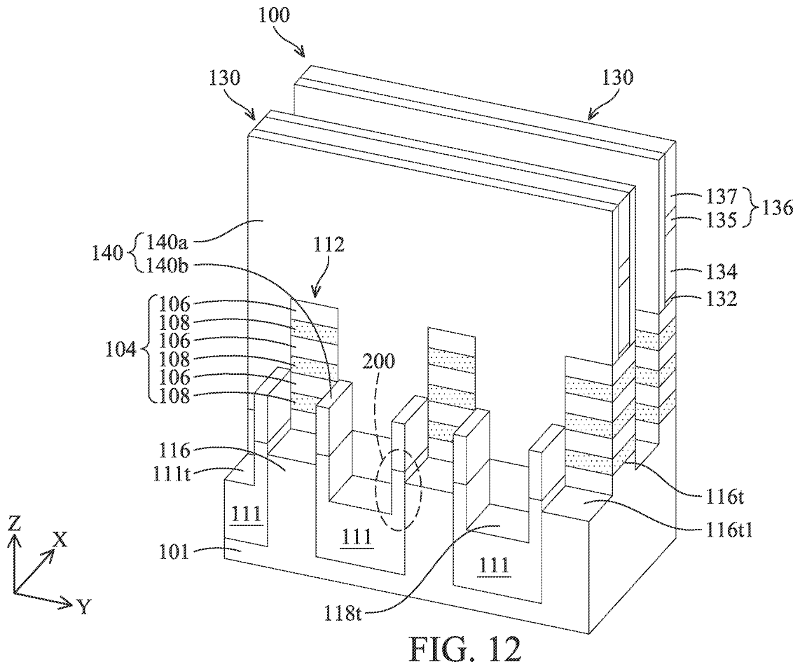

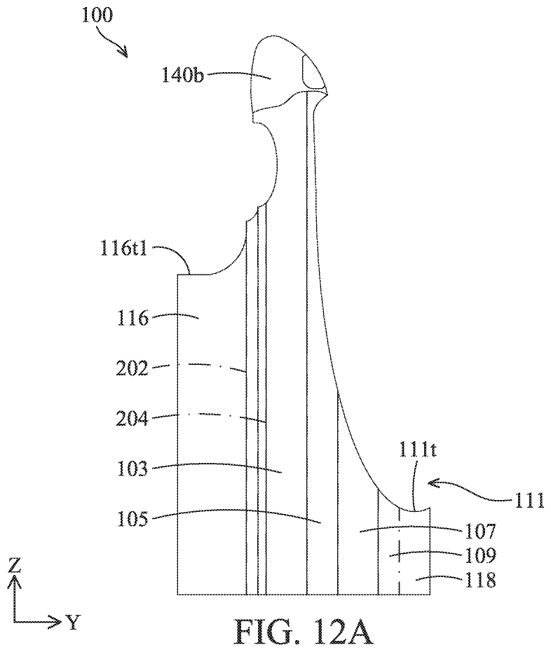

As shown in FIG. 12, one or more etch processes are performed to recess the exposed second portions of the fin structures 112 not covered by the sacrificial gate structures 130 (and the portions of the gate spacer layer 138 formed on sidewalls of the sacrificial gate structures 130) and to remove portions of the gate spacer layer 138. The portions of the gate spacer layer 138 formed on sidewalls of the mask layer 136 may be also recessed. The one or more etch processes may include a dry etch, such as a RIE, NBE, or the like, and/or a wet etch, such as using tetramethylammonium hydroxide (TMAH), ammonium hydroxide (NH₄OH). The one or more etch processes form gate spacers 140 including a first portion 140a formed on sidewalls of the sacrificial gate electrode layer 134 and second portions 140b formed on the second portions of the insulating structures 111. In some embodiments, the one or more etch processes also remove portions of the second portions of the insulating structures 111, as shown in FIG. 12. As a result, the top surface 111t of the second portion of the insulating structures 111 is located at a level substantially below a top surface 116t1 of the well portion 116 after the one or more etch processes. The top surface 116t1 may be below the level of the top surface 116t, as shown in FIG. 12.

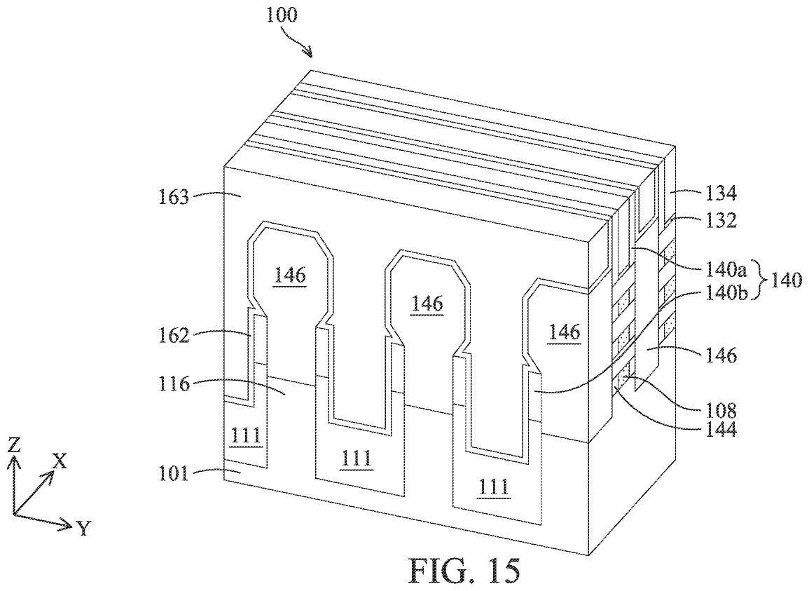

FIG. 12A is a cross-sectional side view of a portion 200 of the semiconductor device structure 100 of FIG. 12, in accordance with some embodiments. As shown in FIG. 12A, the first conformal layer 103, the second conformal layer 105, the third conformal layer 107, and the fourth conformal layer 109 are recessed by the one or more etch processes to recess the exposed second portions of the fin structures 112. In some embodiments, the one or more etch processes also remove the second insulating material 119 and recess the first insulating material 118, as shown in FIG. 12A. In some embodiments, the semiconductor device structure 100 includes the semiconductor layer 202 and an oxide layer 204. The semiconductor layer 202 may include crystalline silicon, and the oxide layer 204 may include silicon oxide. In some embodiments, the semiconductor layer 202 is formed on the fin structures 112, and the first conformal layer 103 is formed on the semiconductor layer 202. The oxide layer 204 is formed by oxidizing the semiconductor layer 202 during the first anneal process. As shown in FIG. 12A, the semiconductor layer 202 and the oxide layer 204 are recessed along with the fin structures 112, and a portion of the first conformal layer 103 adjacent the oxide layer 204 is also removed. As described above, the oxidation of the fourth conformal layer 109 densifies the first, second, and third conformal layers 103, 105, 107 and improves the film quality of the first, second, and third conformal layers 103, 105, 107. As a result, the second and/or the first conformal layer 105, 103 are not laterally etched through. In other words, the sidewall of the well portion 116 is not exposed after the one or more etch processes. If the first, second, and third conformal layers 103, 105, 107 are not present, the one or more etch processes may remove portions of the oxide layer 204 and the semiconductor layer 202 to expose the sidewall of the well portion 116. As a result, S/D regions 146 (FIG. 15) may be formed on the sidewalls of the well portion 116, which may lead to current leakage.

As shown in FIG. 12A, in some embodiments, the first insulating material 118 has a first height in Z direction, the fourth conformal layer 109 has a second height substantially higher than the first height, the third conformal layer 107 has a third height substantially higher than the second height, the second conformal layer 105 has a fourth height substantially higher than the third height, and the first conformal layer 103 has a fifth height substantially the same as or higher than the fourth height. In some embodiments, the thicknesses of the first, second, third, and fourth conformal layers 103, 105, 107, 109 may decrease in a direction away from the substrate 101 (upward in the Z direction) as a result of the one or more etch processes.

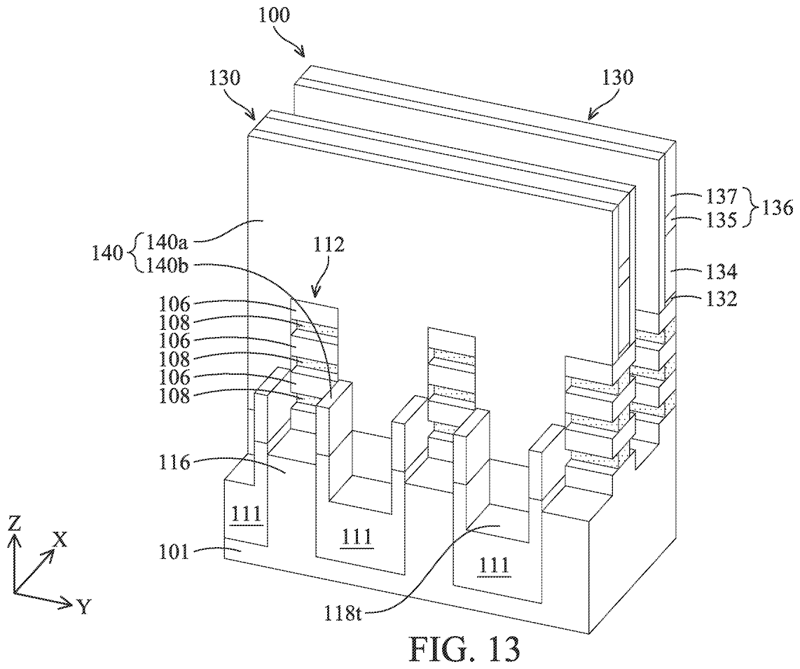

As shown in FIG. 13, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

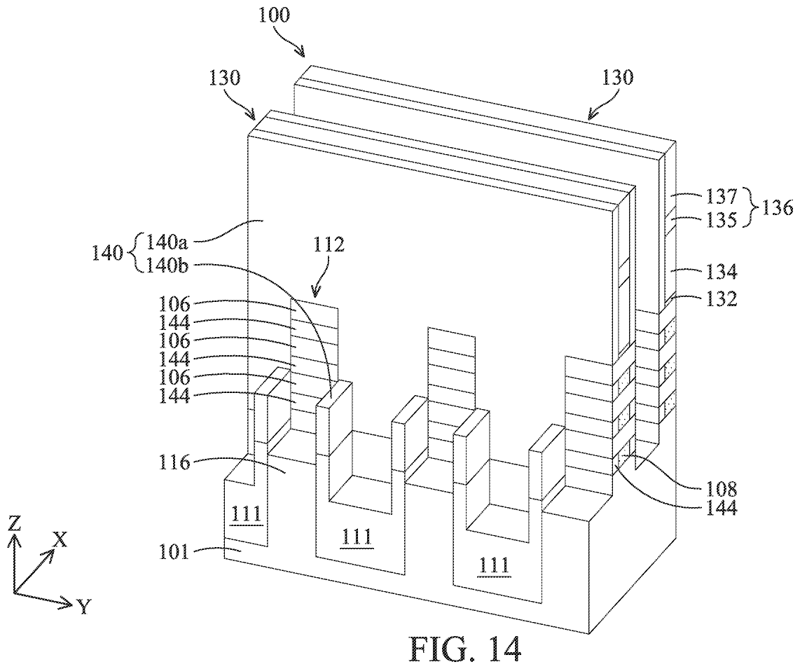

After removing edge portions of each second semiconductor layer 108, a dielectric layer is deposited in the cavities to form dielectric spacers 144, as shown in FIG. 14. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

As shown in FIG. 15, source/drain (S/D) regions 146 are formed from the well portion 116. The S/D regions 146 may grow both vertically and horizontally to form facets, which may correspond to crystalline planes of the material used for the well portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-type FETs (NFETs) or Si, SiGe, Ge for p-type FETs (PFETs). For PFETs, p-type dopants, such as boron (B), may also be included in the S/D regions 146. The S/D regions 146 may be formed by an epitaxial growth method using CVD, ALD or MBE.

As shown in FIG. 15, a contact etch stop layer (CESL) 162 is conformally formed on the exposed surfaces of the semiconductor device structure 100. The CESL 162 covers the sidewalls of the first portion 140a of the gate spacers 140 and is disposed on the second portion 140b of the gate spacers 140 and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134, as shown in FIG. 15. The planarization process may be any suitable process, such as a CMP process. The planarization process removes portions of the ILD layer 163 and the CESL 162 disposed on the sacrificial gate stacks 130. The planarization process may also remove the mask structure 136.

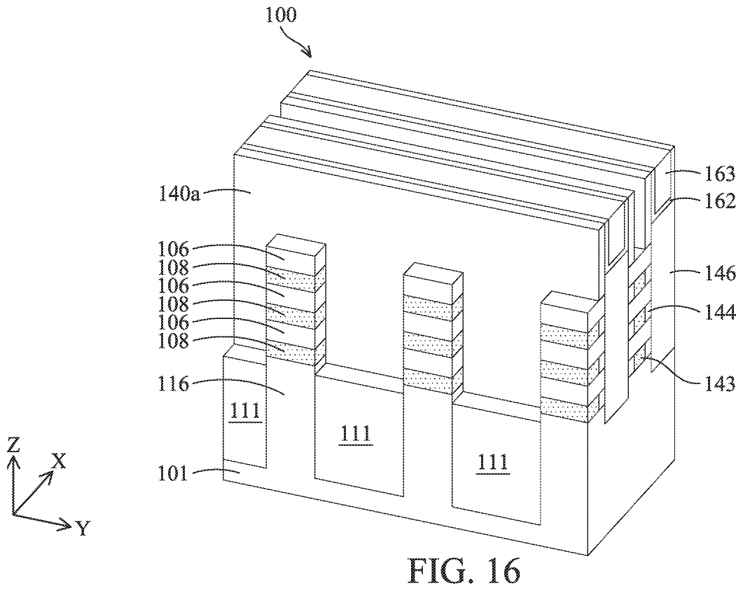

As shown in FIG. 16, the sacrificial gate electrode layer 134 and the sacrificial gate dielectric layer 132 are removed, exposing a portion of the top surface of the topmost first semiconductor layer 106. The first portions of the insulating structure 111 are also exposed. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 140, the insulating structure 111, the ILD layer 163, and the CESL 162.

After removing the sacrificial gate electrode layer 134 and the sacrificial gate dielectric layer 132, the second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 140, the insulating structure 111, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

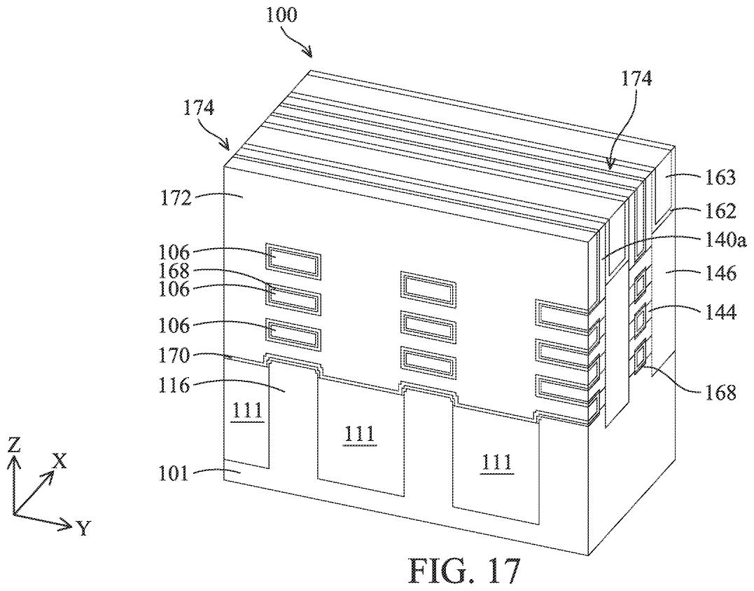

As shown in FIG. 17, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) 168 is formed between the gate dielectric layer 170 and the exposed surfaces of the first semiconductor layers 106. The IL 168 may include an oxide, such as silicon oxide, and may be formed as a result of a clean process. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed.

Embodiments of the present disclosure provide a semiconductor device structure and methods of forming the same. The semiconductor device structure 100 includes an insulating structure 111 having first, second, third, and fourth conformal layers 103, 105, 107, 109. Some embodiments may achieve advantages. For example, the conformal layers 103, 105, 107, 109 protects sidewalls of a well portion 116 during recessing portions of fin structures 112. As a result, epitaxial features are not formed on sidewalls of the fin structures 112.

An embodiment is a method. The method includes forming a first fin structure and a second fin structure from a substrate, depositing a first conformal layer over the first and second fin structures and between the first and second fin structures, depositing a second conformal layer on the first conformal layer, depositing a third conformal layer on the second conformal layer, depositing a fourth conformal layer on the third conformal layer, depositing a first insulating material on the fourth conformal layer between the first and second fin structures, and depositing a second insulating material on the first insulating material. The first and second fin structures are embedded by the second insulating material. The method further includes removing portions of the second insulating material and the first, second, third, and fourth conformal layers to expose the first and second fin structures.

Another embodiment is a method. The method includes forming a first fin structure and a second fin structure from a substrate, depositing a first conformal layer over the first and second fin structures and between the first and second fin structures, depositing a second conformal layer on the first conformal layer, depositing a third conformal layer on the second conformal layer, depositing a fourth conformal layer on the third conformal layer, depositing a first insulating material on the fourth conformal layer between the first and second fin structures, and performing a first anneal process. The fourth conformal layer expands during the first anneal process and causes densities of the first, second, and third conformal layers to increase. The method further includes depositing a second insulating material on the first insulating material, and the first and second fin structures are embedded by the second insulating material. The method further includes removing portions of the second insulating material and the first, second, third, and fourth conformal layers to expose tops of the first and second fin structures, performing a second anneal process, and recessing the second insulating material and the first, second, third, and fourth conformal layers.

A further embodiment is a semiconductor device structure. The structure includes a first source/drain region disposed over a substrate, a first well portion disposed below the first source/drain region, a second source/drain region disposed over the substrate, a second well portion disposed below the second source/drain region, and an insulating structure disposed between the first and second well portions. The insulating structure includes an insulating material having a first height, a first conformal layer in contact with the insulating material, and the first conformal layer has a second height different from the first height. The insulating structure further includes a second conformal layer in contact with the first conformal layer, and the second conformal layer has a third height different from the second height. The insulating structure further includes a third conformal layer in contact with the second conformal layer, and the third conformal layer has a fourth height different from the third height.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a first fin structure and a second fin structure from a substrate;
depositing a first conformal layer over the first and second fin structures and between the first and second fin structures;
depositing a second conformal layer on the first conformal layer;
depositing a third conformal layer on the second conformal layer;
depositing a fourth conformal layer on the third conformal layer;
depositing a first insulating material on the fourth conformal layer between the first and second fin structures;
depositing a second insulating material on the first insulating material, wherein the first and second fin structures are embedded by the second insulating material; and
removing portions of the second insulating material and the first, second, third, and fourth conformal layers to expose the first and second fin structures.

2. The method of claim 1, wherein each of the first and second fin structures comprises alternating first and second semiconductor layers disposed on a well portion.

3. The method of claim 2, wherein the well portion has a first top surface, and top surfaces of the second insulating material, the first conformal layer, the second conformal layer, the third conformal layer, and the fourth conformal layer are located at a level at or below the first top surface.

4. The method of claim 1, wherein the first and second insulating materials have a total thickness, and the second insulating material has a first thickness that is about 15 percent to about 45 percent of the total thickness.

5. The method of claim 4, wherein the first insulating material has a second thickness greater than the first thickness.

6. The method of claim 4, wherein the first thickness ranges from about 50 nm to about 150 nm, and the second thickness ranges from about 200 nm to about 300 nm.

7. The method of claim 1, further comprising:
forming a sacrificial gate stack on a first portion of the first and second fin structures; and
recessing a second portion of the first and second fin structures, wherein the first, second, third, fourth conformal layers, and the first insulating material are recessed, and the second insulating material is removed during the recessing the second portion of the first and second fin structures.

8. A method, comprising:
forming a first fin structure and a second fin structure from a substrate;
depositing a first conformal layer over the first and second fin structures and between the first and second fin structures;
depositing a second conformal layer on the first conformal layer;
depositing a third conformal layer on the second conformal layer;
depositing a fourth conformal layer on the third conformal layer;
depositing a first insulating material on the fourth conformal layer between the first and second fin structures;
performing a first anneal process, wherein the fourth conformal layer expands during the first anneal process and causes densities of the first, second, and third conformal layers to increase;
depositing a second insulating material on the first insulating material, wherein the first and second fin structures are embedded by the second insulating material;
removing portions of the second insulating material and the first, second, third, and fourth conformal layers to expose tops of the first and second fin structures;
performing a second anneal process; and
recessing the second insulating material and the first, second, third, and fourth conformal layers.

9. The method of claim 8, wherein the fourth conformal layer comprises a semiconductor.

10. The method of claim 9, wherein fourth conformal layer is oxidized by the first anneal process.

11. The method of claim 8, wherein the third conformal layer comprises carbon, and the carbon diffuses into the first insulating material during the first anneal process.

12. The method of claim 11, wherein the second conformal layer comprises nitrogen, and the nitrogen diffuses into the first insulating material during the first anneal process.

13. The method of claim 8, further comprising:
forming a sacrificial gate stack on a first portion of the first and second fin structures;
forming a gate spacer;
recessing a second portion of the first and second fin structures, wherein the gate spacer, the first, second, third, fourth conformal layers, and the first insulating material are recessed, and the second insulating material is removed during the recessing the second portion of the first and second fin structures.

14. The method of claim 13, wherein the gate spacer is in contact with the first conformal layer.

15. The method of claim 8, further comprising depositing a semiconductor layer over the first and second fin structures and between the first and second fin structures, wherein the first conformal layer is deposited on the semiconductor layer.

16. The method of claim 15, wherein the semiconductor layer is oxidized during the first anneal process.

17. A semiconductor device structure, comprising:
a first source/drain region disposed over a substrate;
a first well portion disposed below the first source/drain region;
a second source/drain region disposed over the substrate;
a second well portion disposed below the second source/drain region; and
an insulating structure disposed between the first and second well portions, the insulating structure comprising:
an insulating material having a first height;
a first conformal layer in contact with the insulating material, wherein the first conformal layer has a second height different from the first height;
a second conformal layer in contact with the first conformal layer, wherein the second conformal layer has a third height different from the second height; and
a third conformal layer in contact with the second conformal layer, wherein the third conformal layer has a fourth height different from the third height.

18. The semiconductor device structure of claim 17, further comprising a fourth conformal layer in contact with the third conformal layer, wherein the fourth conformal layer has a fifth height different from the third height.

19. The semiconductor device structure of claim 17, wherein the first, second, third, and fourth conformal layers each has a thickness that decreases in a direction away from the substrate.

20. The semiconductor device structure of claim 17, wherein the first conformal layer comprises an oxide, the second conformal layer comprises carbon, and the third conformal layer comprises nitrogen.
